(19) United States
(12) Patent Application Publication
(10) Pub. No.: US 2016/0138184 A1
(43) Pub. Date: May 19, 2016

(54) MELT SURFACE FLOW FIELD MEASUREMENT METHOD FOR ARTIFICIAL CRYSTAL GROWTH SYSTEMS AND CRYSTAL GROWTH APPARATUS UTILIZING THE METHOD

(71) Applicant: PO-CHUNG WANG, Taipei City (TW)

(72) Inventors: PO-CHUNG WANG, Taipei City (TW); CHUNG-HSIEN KOU, New Taipei City (TW)

(21) Appl. No.: 14/540,763

(22) Filed: Nov. 13, 2014

(51) Int. Cl. C30B 15/26; G01F 15/06; C30B 29/20; C30B 15/14; C30B 17/00

(52) U.S. Cl. CPC C30B 15/26; C30B 15/14; C30B 17/00; C30B 29/20; G01F 15/06

(57) ABSTRACT

A melt surface flow field measurement method that captures flow rates at multiple tracking points and their mapping on melt surface for artificial crystal growth systems includes the following steps: (A) capture two consecutive images of the melt surface at a time interval of Δt; (B) define the significant regions in the first image as a plurality of first grid regions, then calculate centroid coordinates of the first grid regions; (C) define the regions in the second image corresponding to the significant regions in the first image as a plurality of second grid regions, then calculate centroid coordinates of the second grid regions; (D) lay the second set of centroid coordinates over the first grid regions, and calculate the distances between corresponding centroid coordinates to determine the displacement of the identified significant regions; and (E) divide the displacements by the time interval Δt to determine the flow rate and direction of each identified significant region on melt surface at their centroids—the tracking points.

### BACKGROUND OF THE INVENTION

1. Field of the Invention

The present invention relates to melt surface flow field measurement methods that capture flow rates at multiple tracking points and their mapping on melt surface for artificial crystal growth systems, specifically, to a melt surface flow field measurement method that tracks the centroid movement of identified significant regions on melt surface topography and a crystal growth apparatus utilizing the method.

2. Description of the Prior Art

Kyropoulos method is widely applied in sapphire crystal growth. It entails heating a raw material in a crucible until the raw material reaches its melting point and thus becomes a liquid melt then lowering a monocrystalline seed crystal until the monocrystalline seed crystal comes into contact with the melt surface, such that a single crystal of the same crystalline structure gradually grows at the solid-liquid interface between the seed crystal and the melt. In the initial stage of crystal growth, the seed crystal is gently pulled upward, such that a conical neck is initiated and developed on the surface of the melt. Once the neck has grown to a certain degree, the upward pull of the seed crystal stops. Meanwhile control the cooling rate for the single crystal to grow gradually from the neck downward until a complete monocrystalline ingot is formed.

Another common crystal growth technique is known as Czochralski method, which is similar to Kyropoulos method except continuously pulling the seed crystal upward while rotating the seed crystal.

The conventional crystal growth process is very operator dependent. It relies on the operators—experienced crystal growth engineers to control such process parameters as melt temperature, the time to lower a seed crystal, crystal pulling speed, the time to stop pulling crystal, and cooling temperature. About 60%-70% of the yield of crystal growth depends on crystal growth engineers' expertise and experience. However, crystal growth engineers have a long learning curve to operate high-tech instruments, and are required to spend significant amount of time on learning through trial-and-error process in order to accumulate experience. A crystal growing process which depends on crystal growth engineers' expertise and experience takes at least 10 days, during which crystal growth engineers spend several hours performing the seed crystal lowering process. The process requires that the melt be controlled at an appropriate temperature range. If the melt temperature is overly high, the seed crystal will melt during the lowering process. Conversely, if the melt temperature is too low, the melt surface will cake. Either case, the crystal grow process cannot proceed further until a proper melt temperature is achieved for initial crystal grow at the interface between seed crystal and melt surface. Unfortunate the control of proper melt temperature for lowering and pulling seed crystal varies among crystal grow engineers leading to low stability and low reproducibility.

Temperature sensors, such as image color temperature sensors, infrared thermometers, thermal image cameras, and thermocouples, are mounted on some crystal growers for use with the aforementioned crystal growing process, to determine melt temperature. However, the temperature sensors have the following drawbacks: 1. image color temperature sensors have a low resolution in determining temperature and thus are not effective in determining the time to lower the seed crystal; 2. infrared thermometers have carbon accumulated at the eyepiece lens and thus are likely to read temperature wrong, not to mention that they have low temperature resolution; and 3. the location of a thermocouple sensor is a fixed point nears the melt, and thus the thermocouple sensor fails to accurately measure the actual temperature of the melt in the crucible.

According to the prior art, in addition to the aforementioned temperature sensors, crystal growth engineers observe the change of wavy melt surface topography with the naked eye and determine the time to lower the seed crystal according to their training and experience. Due to active thermal convection in the melt, the melt surface forms wavy topography. As a result of light diffuse reflection and contrast between wave crest and trough, significant regions in the wavy melt surface topography can be observed. Experienced crystal growth engineers track the movement of the significant regions to determine the time to lower the seed crystal, as the movement of the significant regions on melt surface is an indicator of melt surface flow rate that correlates with melt temperature. The melt surface flow rate increases when the melt temperature increases, and vice versa. The crystal growth engineers observe the change of wavy melt surface topography to estimate the melt temperature and thereby determine the time to lower the seed crystal. Nonetheless, the method relies solely upon the crystal growth engineers' training and experience to observe the abstract and situation dependent melt surface, as a result the seeding process is very lengthy and with low stability.

### SUMMARY OF THE INVENTION

In view of the aforementioned drawbacks of the prior art, one the objectives of the present invention is to provide a melt surface flow field measurement method for artificial crystal growth systems and a crystal growth apparatus utilizing the method without the drawbacks of the prior art, namely the seed crystal lowering process that is very lengthy and manifests low stability.

In order to achieve the above and other objectives, the present invention provides a melt surface flow field measurement method for artificial crystal growth systems. The melt surface flow field measurement method comprises the steps of: (A) capture two consecutive images of the melt surface at a time interval of At; (B) define the significant regions in the first image as a plurality of first grid regions; then calculate centroid coordinates of the first grid regions; (C) define the regions in the second image corresponding to the significant regions in the first image as a plurality of second grid regions, then calculate centroid coordinates of the second grid regions; (D) lay the second set of centroid coordinates over the first grid regions, calculate the distances between corresponding centroid coordinates to determine the displacement of the identified significant regions; and (E) divide the displacements by Δt to determine the flow rate and direction of each identified significant region on melt surface.

Preferably, the method further comprises the steps of: repeating steps (A)-(D) multiple times, treating a preceding said second image as a next said first image to obtain consecutive displacements of a plurality of centroids in at least two images; and calculating the melt surface flow rates of at least two consecutive images according to consecutive displacements of the plurality of centroids and At in step (E).

Preferably, step (D) of the method further comprises calculating speeds of the centroids according to displacements and At of the plurality of centroids, defining a said centroid as an unreliable centroid if the speed of the centroid is larger than 15 cm/s, remove the displacement of the unreliable centroid from the subsequent calculation process.

Preferably, the method further comprises defining a centroid as an unreliable centroid if a difference in displacement between consecutive said centroids exceeds a predetermined threshold, remove the displacement of the unreliable centroid from the subsequent calculation process.

Preferably, step (D) of the method further comprises calculating the average and standard deviation of distances traveled by the centroids assuming that the distances traveled by the centroids are normally distributed, defining a centroid as an unreliable centroid when the distance traveled by the centroid differs from the average distance by at least two standard deviations, remove the displacement of the unreliable centroid from the subsequent calculation process.

Preferably, the method further comprises calculating the consecutive speed of the plurality of centroids according to consecutive displacements of the plurality of centroids and a time interval at which the two images are captured, and defining the melt surface flow rate indicator according to the average consecutive speed of the plurality of centroids.

Preferably, the method further comprises calculating the consecutive velocity of the plurality of centroids according to consecutive displacements of the plurality of centroids and a time interval at which the two images are captured, and defining the melt surface flow rate indicator according to the average magnitude of consecutive velocity of the plurality of centroids.

Preferably, according to the method, when the difference between a consecutive velocity of a centroid and an average consecutive velocity of other said centroids exceeds a predetermined threshold, the centroid is defined as an unreliable centroid, and a displacement of the unreliable centroid is removed from the subsequent calculation process.

Preferably, step (A) of the method further includes performing image processing, preferably binarization, on the first image and the second image.

Preferably, according to the method, a time interval At between two consecutive images are captured is ⅙ second or less.

In order to achieve the above and other objectives, the present invention further provides an artificial crystal growth apparatus utilizing the melt surface flow field measurement method.

Preferably, regarding the aforementioned artificial crystal growth apparatus, the heating power of a heating coil is controlled according to the measured melt surface flow field and flow rate indicator.

Preferably, regarding the aforementioned artificial crystal growth apparatus, the seed crystal descending and ascending device is controlled according to the measured melt surface flow field and flow rate indicator.

A melt surface flow field measurement method for artificial crystal growth according to the present invention is effective in measuring melt surface flow rate at multiple tracking points and their mapping. Furthermore, an artificial crystal growth apparatus utilizing the method is effective in reducing the probability of seed crystal melting and melt surface caking during the seed crystal lowering process and effective in reducing total process time.

### BRIEF DESCRIPTION OF THE DRAWINGS

Objectives, features, and advantages of the present invention are hereunder illustrated with specific embodiments in conjunction with the accompanying drawings, in which:

FIG. 1 is a schematic view of a first image and a second image according to the first embodiment of the present invention;

FIG. 2 is a schematic view of the first image and the second image which have undergone image processing according to the first embodiment of the present invention;

FIG. 3 is a schematic view of the result of calculation of a plurality of the first centroid coordinates and the second centroid coordinates according to the first embodiment of the present invention; and

FIG. 4 is a schematic view which illustrates how to calculate displacements of centroids according to the first embodiment of the present invention.

### DETAILED DESCRIPTION OF THE EMBODIMENTS

### First Embodiment

The first embodiment of the present invention is applied in melt surface flow field measurement, using two images.

An artificial crystal growing process is performed with a sapphire crystal grower. The artificial crystal growing process entails putting high-purity aluminum oxide (Al₂O₃) raw material in a crucible of the crystal grower and then heating the high-purity aluminum oxide raw material in the crucible with a heating coil until it melts, wherein, at this point in time, due to active thermal convection in the melt, the melt surface forms wavy topography. As a result of light diffuse reflection and contrast between wave crest and trough, significant regions in the wavy melt surface topography can be observed. The steps of measuring the melt surface flow field according to the first embodiment are described as follows:

Step (A): capture consecutive melt flow images.

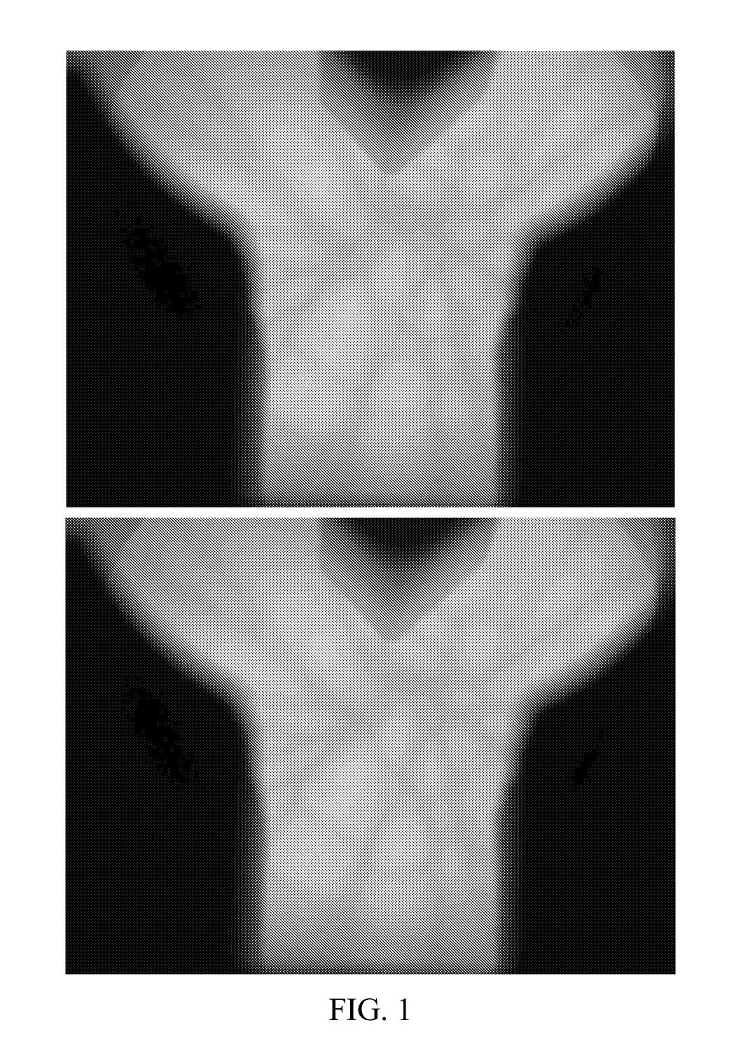

Two consecutive flow images of a melt surface captured with an industrial digital camera are shown in FIG. 1. The first image is shown on the top and the second image is shown on the bottom. The two melt surface images were captured through the viewing window of the sapphire crystal grower at a time interval Δt of ⅙ second (30 FPS), with a resolution of 1280×963 pixels. The present invention is not restrictive of the type, time interval, resolution, and mounted position of the camera used in step (A), as the present invention will be practicable, provided that the flow images of the melt surface are effectively captured. As the brightness of the melt surface varies with temperature, a camera with an automatic aperture and autofocus is preferred. The time interval At between the two images is not necessarily ⅙ second; hence, the present invention will be practicable, provided that the time interval At is equal to or less than a predetermined threshold, such that the correlation between any two consecutive images in a subsequent step can be easily determined. In the first embodiment, the length or area of images of objects is presented initially in pixels such that, as shown in the two images, an object (for example, a seed crystal at the top of the two images in FIG. 1) of any known length is regarded as the reference object, and the pixel values are converted to calculate the actual length and area of the object.

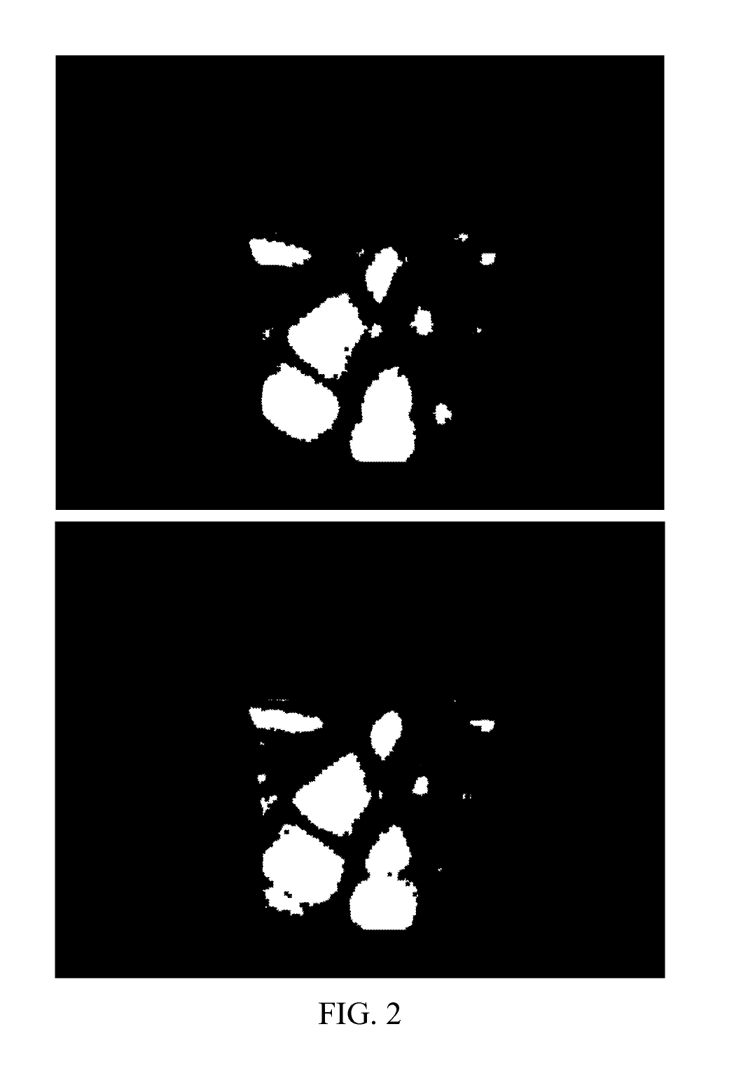

Step (A) further includes performing image processing, that is, binarization, on the first image and second image obtained. Referring to FIG. 2, the processed first image is shown on the top, whereas the processed second image is shown on the bottom. As shown in FIG. 2, due to the image processing, the grids of the melt surface can be clearly discerned. The purpose of the image processing is to precisely define the grid regions in the subsequent step; however, the image processing is optional, as far as the present invention is concerned.

Step (B): define the significant regions as grid regions and centroid coordinates in the first image.

Step (B) is applicable to image processing software and entails defining the areas of the processed first image as a plurality of first grid regions A¹₁˜A¹ₙ, calculating first centroid coordinates of the first grid regions A¹₁˜A¹ₙ, and denoting the first centroid coordinates with M¹₁˜M¹ₙ, wherein the significant regions defined as melt grids are formed as a result of the active thermal convection of the melt.

In the present invention, the term “centroid” is well known as the geometric center of a regular or irregular region.

Step (C): define the significant regions as grid regions and centroid coordinates of the second image.

Step (C) is applicable to image processing software and entails defining the areas of the processed second image as a plurality of second grid regions A²₁˜A²ₘ, calculating centroid coordinates of the second grid regions A²₁˜A²ₘ, and denoting the second centroid coordinates with M²₁˜M²ₘ, wherein the significant regions defined as melt grids are formed as a result of the active thermal convection of the melt.

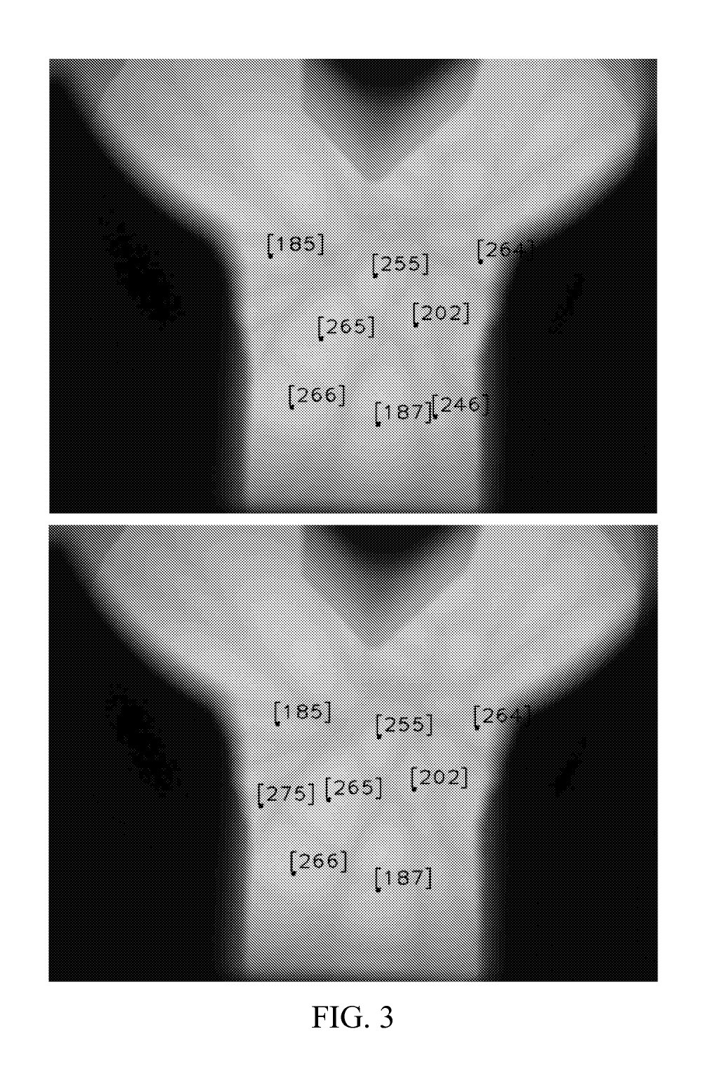

The results of the calculation performed in step (B) and step (C) are shown in FIG. 3. Referring to FIG. 3, the first image is shown on the top, whereas the second image is shown on the bottom, wherein the centroids of each grid region are indicated by dots and identified with specific numbers, respectively.

Step (D): calculate displacements of centroids.

Step (D) entails obtaining the second centroid coordinates inside the first grid regions, calculating a displacement between each second centroid coordinate and a corresponding one of the first centroid coordinates in each said first grid region so as to obtain the displacements of a plurality of centroids. Step (D) is described in detail below.

When any one of the second centroid coordinates M²₁˜M²ₘ is located inside the first grid regions A¹₁, centroid displacements between the second centroid coordinates M²ₓ and the first centroid coordinates M¹₁ are calculated (where 1≦x≦m), and centroid displacements inside the first grid regions A¹₂˜A¹ₙ are calculated in the same way, so as to obtain the displacements of a plurality of centroids.

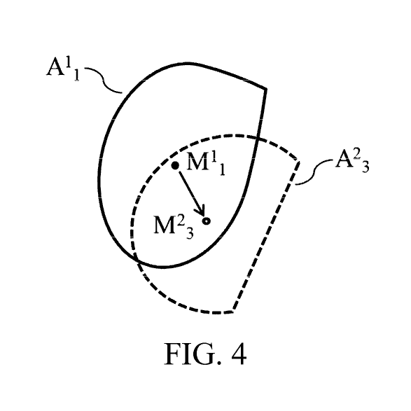

FIG. 4 is a schematic view which illustrates how to calculate displacements of centroids according to the first embodiment of the present invention. The following description of the calculation of centroid coordinates in step (D) is exemplified by FIG. 4. The area enclosed by a solid line shown in FIG. 4 is a grid region A¹₁ of the first image. The centroid coordinates M¹₁ of the grid region A¹₁ are indicated by solid dots shown in FIG. 4. The area enclosed by a dashed line shown in FIG. 4 is a grid region A²₃ of the second image. The centroid coordinates M²₃ of the grid region A²₃ are indicated by hollow dots shown in FIG. 4. Referring to FIG. 4, the centroid coordinates M²₃ are located inside the grid region A¹₁ and thus meet the requirements set forth in step (D), such that it is feasible to determine, according to the requirements, that the grid region A¹₁ and the grid region A²₃ are the same grid region in the two images. Once the requirements are met, step (D) of the method will entail calculating the centroid displacement between the centroid coordinates M²₃ and the centroid coordinates M¹₁, such that the calculated centroid displacement can be applied in the melt surface flow rate measurement in the subsequent step.

Step (E): calculate melt surface flow rate.

Step (E) entails calculating melt surface flow rate according to displacements of the plurality of centroids and Δt. Specifically speaking, in step (E), velocities of a plurality of centroids are calculated with the equation v=Δs/Δt, where v denotes the velocity of the centroid, As denotes the displacement of the centroid, and At denotes the time interval at which two images are captured. Furthermore, step (E) entails calculating the average of the velocities of the plurality of centroids to obtain its average velocity and then defining the melt surface flow rate with the average velocity.

The velocities of the plurality of centroids are vectors and thus each described by both a magnitude and a direction. If velocities of the plurality of centroids are in different directions, the magnitude of the average velocity of the plurality of centroids may less than the actual melt surface flow rate. In view of this, the first embodiment of the present invention necessitates calculating the speeds of a plurality of centroids as described below. The distance Δx (a scalar) traveled by a centroid is calculated according to the magnitude of a centroid displacement As (a vector), and the speeds of a plurality of centroids are calculated with the equation v=Δx/Δt, so as to calculate the average speed of the plurality of centroids and then define the melt surface flow rate with the average speed thus calculated.

### Second Embodiment

The second embodiment of the present invention is applied in melt surface flow rate measurement, using a plurality of images.

The method in the second embodiment comprises the steps of: repeating steps (A)˜(D) of the first embodiment multiple times, treating a preceding said second image as a next said first image to obtain consecutive displacements of a plurality of centroids in at least two images, and defining the melt surface flow rate according to the consecutive displacements and Δt of the plurality of centroids in step (E) of the first embodiment. The second embodiment is not restrictive of the number of times steps (A)˜(D) of the first embodiment are carried out repeatedly.

In the second embodiment, the flow image of the melt surface is captured every ⅙ second and in a total of six instances to obtain the first to sixth images, and steps (A)˜(D) of first embodiment are repeatedly carried out in a total of five instances to obtain five consecutive displacements of each centroid.

The method in the second embodiment involves taking the average of the five consecutive displacements of each centroid to obtain the average consecutive displacement of a plurality of centroids, calculating the consecutive velocities of a plurality of centroids with the equation v=Δs/Δt, where v denotes consecutive velocity of the centroid, Δs denotes average consecutive displacement, and Δt denotes the time interval at which two images are captured, calculating the average of the consecutive velocities of the plurality of centroids to obtain the average consecutive velocity, and defining the melt surface flow rate with the average consecutive velocity.

The second embodiment and the first embodiment have a common feature, that is, having an alternative option of calculating consecutive speeds of a plurality of centroids. It entails calculating average consecutive distance Δx (a scalar) traveled by a centroid according to the magnitude of an average consecutive displacement Δs (a vector), calculating consecutive speeds of a plurality of centroids with the equation v=Δx/Δt, calculating the average of consecutive speeds of the plurality of centroids to obtain an average consecutive speed, and defining the melt surface flow rate with the average consecutive velocity.

### Third Embodiment

The third embodiment of the present invention is applied in the elimination of an unreliable region and displacement of an unreliable centroid.

A melt is a fluidic object under observation. Neither its direction nor its size is fixed. In the third embodiment, an unreliable centroid and an unreliable region are further defined, and the elimination of the displacement of the unreliable centroid and unreliable region from the subsequent calculation process is conducive to obtaining a highly credible result of calculation.

In the third embodiment, not only is the melt surface flow rate defined with the method described in the second embodiment, but the unreliable centroid and unreliable region are also defined according to parameters, such as velocities of centroids and area of grid regions. In the third embodiment, the known dimensions of a seed crystal in an image are deemed a benchmark, and pixel value is converted into the actual length or area to become a criterion, but the present invention is not limited thereto, as it is also feasible to see the pixel value as the criterion directly on condition that the image resolution is constant.

### Criterion

In step (D), velocities of the centroids are calculated according to the displacement and At of the plurality of centroids such that, if the velocity of a centroid exceeds 15 cm/s, the centroid will be defined as an unreliable centroid, and the displacement of the unreliable centroid will be removed from the subsequent calculation process.

In the process of repeating steps (A)˜(D), if the included angle between the preceding displacement of a centroid and the next displacement of the centroid is larger than 60°, the centroid will be defined as an unreliable centroid, and the displacement of the unreliable centroid will be removed from the subsequent calculation process.

Step (D) involves calculating the distances traveled by a plurality of centroids according to the displacements of the plurality of centroids, calculating the average and standard deviation of the distances traveled by the plurality of centroids (assuming the distances traveled by the plurality of centroids are normally distributed), defining a centroid as an unreliable centroid when the distance traveled by the centroid differs from the average distance by at least two standard deviations, remove the displacement of the unreliable centroid from the subsequent calculation process.

### Fourth Embodiment

measurement of preferred melt surface flow rate range

Crystal growth raw material inside the crucible is heated up in the sapphire crystal grower until the raw material melts. Then, a seed crystal is lowered into the melt at a speed of 0.5 mm/min. During the seed crystal lowering process, the melt surface flow rate is measured with the method of the third embodiment. Once the melting of the seed crystal is observed, it will indicate that the temperature of the melt is too high, that is, the melt surface flow rate is too high. To make the required correction, it is necessary to reduce the heating power of the coil and lift the seed crystal. The seed crystal can be lowered again, as soon as the melt surface flow rate slows down significantly. The aforementioned steps are repeated until the seed crystal comes into contact with the melt surface. At this point in time, the melt surface flow rate is measured and recorded.

The aforementioned steps are repeated to measure the melt surface flow rate in multiple instances of contact between the seed crystal and the melt surface, and a preferred melt surface flow rate range is 5 cm/s˜7cm/s according to the flow rates.

### Fifth Embodiment

artificial crystal growth apparatus applicable to the third embodiment

In the fifth embodiment, an artificial crystal growth apparatus is a sapphire crystal grower equipped with a melt surface flow rate measurement device and adapted to measure a melt surface flow rate with the method of the third embodiment. The sapphire crystal grower comprises a camera, a calculation unit, a control unit, a crucible, a heating coil, and a seed crystal descending and ascending device. The camera is used to capture consecutive melt surface images and sending the images to the calculation unit. After receiving the images, the calculation unit performs image processing as well as measures and calculates the melt surface flow rate as described in the third embodiment, and then sends the melt surface flow rate data to the control unit. After receiving the melt surface flow rate data from the calculation unit, the control unit controls a heating power of the heating coil and the seed crystal descending and ascending device according to the flow rate data. The crucible contains an aluminum oxide raw material. The heating coil winds around the crucible to heat the aluminum oxide raw material in the crucible until the raw material starts to melt. The seed crystal descending and ascending device lowers and lifts a seed crystal. The control unit increases the heating power of the heating coil as soon as the melt surface flow rate data received by the control unit indicates that the melt surface flow rate is less than the lower limit of a preferred melt surface flow rate range. Conversely, the control unit decreases the heating power of the heating coil as soon as the melt surface flow rate data received by the control unit indicates that the melt surface flow rate exceeds the upper limit of a preferred melt surface flow rate range. In doing so, the melt surface flow rate is kept within the preferred melt surface flow rate range, and the seed crystal descending and ascending device will keep lowering the seed crystal, provided that the melt surface flow rate data received by the control unit indicates that the melt surface flow rate falls within a preferred melt surface flow rate range. The preferred melt surface flow rate range for the measurement method of the fourth embodiment and is 5 cm/s˜7 cm/s.

Repeated tests confirm that the sapphire crystal grower of the fifth embodiment utilizing the method described in the third embodiment to control the melt surface flow rate is effective in preventing seed crystal melting and melt surface caking, and effective in reducing the seed crystal lowering process by two hours on average when compared with the prior art.

In conclusion, a melt surface flow field measurement method for artificial crystal growth according to the first through fifth embodiments of the present invention is effective in measuring a melt surface flow rate. Furthermore, an artificial crystal growth apparatus utilizing the method is effective in reducing the probability of seed crystal melting and melt surface caking during a seed crystal lowering process and effective in reducing overall process time.

The present invention is disclosed above by preferred embodiments. The preferred embodiments are illustrative of the present invention only, but should not be interpreted as restrictive of the scope of the present invention. All equivalent modifications and replacements made to the aforementioned embodiments should fall within the scope of the present invention. Accordingly, the legal protection for the present invention should be defined by the appended claims.

What is claimed is:

1. A melt surface flow field measurement method that captures flow rates at multiple tracking points and their mapping on melt surface for artificial crystal growth systems includes the following steps:
(A) capture two consecutive images of the melt surface at a time interval of Δt;
(B) define the significant regions in the first image as a plurality of first grid regions, then calculate centroid coordinates of the first grid regions;
(C) define the regions in the second image corresponding to the significant regions in the first image as a plurality of second grid regions, then calculate centroid coordinates of the second grid regions;
(D) lay the second set of centroid coordinates over the first grid regions and calculate the distances between corresponding centroid coordinates to determine the displacement of the identified significant regions; and lastly
(E) divide the displacements by the time interval Δt to determine the flow rate and direction of each identified significant region on melt surface at their centroids—the tracking points.

2. The melt surface flow field measurement method of claim 1, further comprises the steps of: repeating steps (A)˜(D) multiple times, treating a preceding said second image as a next said first image to obtain consecutive displacements of a plurality of centroids in at least two images; and calculating the melt surface flow field of at least two consecutive images according to consecutive displacements of the plurality of centroids and Δt in step (E).

3. The melt surface flow field measurement method of claim 2, wherein step (D) further comprises calculating speeds of the centroids according to displacements of the plurality of centroids and Δt, defining a said centroid as an unreliable centroid if the speed of the centroid is larger than 15 cm/s, remove the displacement of the unreliable centroid from the subsequent calculation process.

4. The melt surface flow field measurement method of claim 3, further comprises defining a centroid as an unreliable centroid if the difference in displacement between consecutive said centroids exceeds a predetermined threshold, remove the displacement of the unreliable centroid from the subsequent calculation process.

5. The melt surface flow field measurement method of claim 4, wherein step (D) further comprises calculating the average and standard deviation of distances traveled by the centroids assuming that the distances traveled by the centroids are normally distributed, define a centroid as an unreliable centroid when the distance traveled by the centroid differs from the average distance by at least two standard deviations, and remove the displacement of the unreliable centroid from the subsequent calculation process.

6. The melt surface flow field measurement method of claim 5, further comprising calculating the consecutive speed of the plurality of centroids according to consecutive displacements of the plurality of centroids and a time interval at which the two images are captured, and defining the melt surface flow rate indicator according to the average magnitude of consecutive speed of the plurality of centroids.

7. The melt surface flow field measurement method of claim 5, further comprising calculating the consecutive velocity of the plurality of centroids according to consecutive displacements of the plurality of centroids and a time interval at which the two images are captured, and defining the melt surface flow rate indicator according to the average magnitude of consecutive velocity of the plurality of centroids.

8. The melt surface flow field measurement method of claim 7, wherein, when the difference between a consecutive speed of a centroid and the average consecutive speed of other said centroids exceeds a predetermined threshold, the centroid is defined as an unreliable centroid, and the a displacement of the unreliable centroid is removed from the subsequent calculation process.

9. The melt surface flow rate measurement method of claim 8, wherein step (A) further includes performing binarization image processing on the first image and the second image.

10. The melt surface flow rate measurement method of claim 9, wherein two consecutive images of the melt surface are captured at a time interval Δt which is ⅙ second or less.

11. An artificial crystal growth apparatus utilizes the melt surface flow field measurement method of claim 1.

12. The artificial crystal growth apparatus of claim 11, wherein a heating power of a heating coil is controlled according to the measured melt surface flow field and flow rate indicator.

13. The artificial crystal growth apparatus of claim 12, wherein a seed crystal descending and ascending device is controlled according to the measured melt surface flow field and flow rate indicator.
